(19) United States
(12) Patent Application Publication
(10) Pub. No.: US 2025/0219229 A1
(43) Pub. Date: Jul. 3, 2025

(54) REPLACEABLE BATTERY

(71) Applicant: TOYOTA JIDOSHA KABUSHIKI KAISHA, Toyota-shi (JP)

(72) Inventors: Yutaroh GOTOH, Toyota-shi (JP); Naoki KASUYA, Kariya-shi (JP); Masataka OGUSHI, Nisshin-shi (JP)

(73) Assignee: TOYOTA JIDOSHA KABUSHIKI KAISHA, Toyota-shi (JP)

(21) Appl. No.: 18/959,818

(22) Filed: Nov. 26, 2024

(30) Foreign Application Priority Data
Dec. 27, 2023 (JP) 2023-220267

(51) Int. Cl. H01M 50/262; B60L 53/80; G01R 31/3835; H01M 10/48; H01M 50/209; H01M 50/249; H01M 50/256; H01M 50/271; H01M 50/30

(52) U.S. Cl. CPC H01M 50/262; B60L 53/80; H01M 10/482; H01M 50/209; H01M 50/249; H01M 50/256; H01M 50/271; H01M 50/394; G01R 31/3835; H01M 2220/20

(57) ABSTRACT

A replaceable battery including: a cell stack; and a case for accommodating the cell stack, in which the case includes: a first member having an L-shaped cross section that includes a bottom plate for supporting the cell stack; a second member having an L-shaped cross section that is arranged to face the first member; a first lid part for closing one opening part of the main body part; and a second lid part having a connector for closing the other opening part of the main body part, and in which the cell stack is arranged closer to a side plate of the first member, the case has a spatial region above the cell stack, and a region of the side plate of the first member overhanging the spatial region and a top plate of the second member are fastened together with a fastening member.

### CROSS REFERENCE TO RELATED APPLICATIONS

This application is based upon and claims the benefit of priority from Japanese patent application No. 2023-220267, filed on Dec. 27, 2023, the disclosure of which is incorporated herein in its entirety by reference.

### BACKGROUND

The present disclosure relates to a replaceable battery.

Patent Literature 1 discloses a replaceable battery detachably mounted on a vehicle. The replaceable battery disclosed in Patent Literature 1 has a battery core pack (cell stack) composed of a plurality of single cells housed in a case.

Patent Literature 1: Japanese Unexamined Patent Publication No. 2019-169337

### SUMMARY

In a replaceable battery of the related art, it is necessary to arrange a cell stack in a case so that the cell stack is located distant from a fastening member in order to prevent interference of the fastening member, which fastens a plurality of members forming the case, with the cell stack, and there is still room for improvement in the space efficiency in the case.

The present disclosure is made in view of the above background, and it is an object of the present disclosure to provide a replaceable battery in which the space efficiency in the battery case can be improved.

An aspect of the present disclosure is a replaceable battery including at least:

a rectangular parallelepiped cell stack having a plurality of battery cells stacked thereon; and

a case for accommodating the cell stack,

in which the case includes:
a first member having an L-shaped cross section that includes a bottom plate for supporting the cell stack and extends along a side surface of the cell stack;
a second member having an L-shaped cross section that is arranged to face the first member to thereby form a rectangular tube shaped main body part with the first member, and extends along a side surface of the cell stack;
a first lid part for closing an opening part at the front end of the rectangular tube shaped main body part; and
a second lid part having a connector for closing an opening part at the rear end of the rectangular tube shaped main body part,

and in which
the cell stack is arranged closer to a side plate of the first member than to a side plate of the second member,
the case has a spatial region above the cell stack, and
a region of the side plate of the first member overhanging the spatial region and a top plate of the second member are fastened together with a fastening member.

In the replaceable battery, among regions of a plurality of members forming the case, regions overhanging the spatial region provided in the upper part of the case are fastened together with a fastening member. As a result, in the replaceable battery, a cell stack can be arranged close to one side plate of the case without causing any interference of the fastening member with the cell stack. As a result, for example, a sufficient spatial region for arranging an electronic device such as a battery monitoring apparatus can be secured between a cell stack and a side plate on the other side of the case. That is, with the use of the aforementioned replaceable battery, the space efficiency in the case can be improved while preventing interference of a fastening member with the cell stack.

According to the present disclosure, it is possible to provide a replaceable battery in which the space efficiency in a battery case can be improved.

The above and other objects, features and advantages of the present disclosure will become more fully understood from the detailed description given hereinbelow and the accompanying drawings.

### BRIEF DESCRIPTION OF DRAWINGS

FIG. 1 is a schematic perspective view showing an external view of a replaceable battery according to a first embodiment;

FIG. 2 is an enlarged schematic perspective view of the periphery of a front case provided at the front end of the replaceable battery according to the first embodiment;

FIG. 3 is an enlarged schematic perspective view of the periphery of a rear case provided at the rear end of the replaceable battery according to the first embodiment;

FIG. 4 is a flowchart showing the flow of assembly of the replaceable battery according to the first embodiment;

FIG. 5 is a schematic perspective view for explaining the flow of assembly of the replaceable battery according to the first embodiment;

FIG. 6 is a schematic perspective view for explaining the flow of assembly of the replaceable battery according to the first embodiment; and

FIG. 7 is a schematic cross-sectional view of the replaceable battery according to the first embodiment.

### DESCRIPTION OF EMBODIMENTS

Hereinafter, the present disclosure will be described through embodiments of the present disclosure. However, the embodiments are not intended to limit the scope of the present disclosure according to the claims. Further, not all of the components/structures described in the embodiments are necessarily indispensable as means for solving the problem. Further, not all of the components/structures described in the embodiments are necessarily indispensable as means for solving the problem. In the figures, the identical reference symbols denote identical structural elements and redundant explanation thereof is omitted.

### First Embodiment

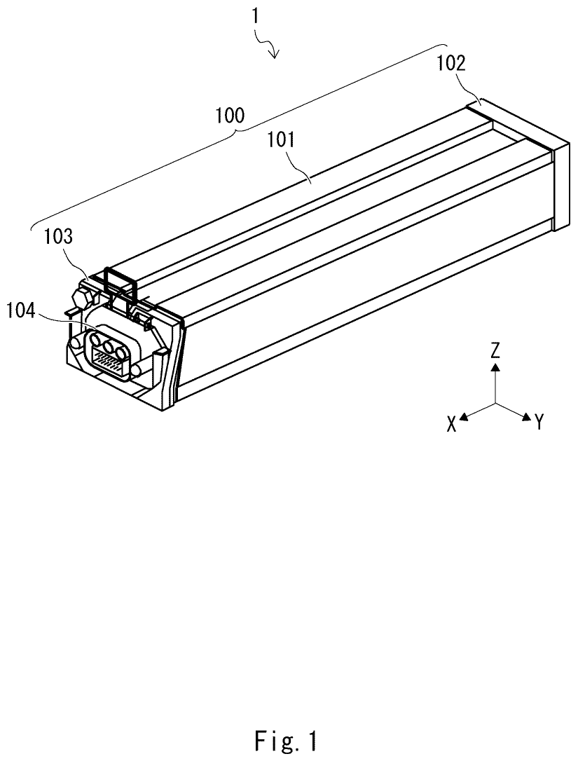

FIG. 1 is a schematic perspective view showing an external view of a replaceable battery 1 according to a first embodiment. The replaceable battery 1 is also referred to as a battery pack, a battery module, or the like, and is detachably attached to a vehicle such as an electric vehicle driven by a motor using electricity as a power source. The replaceable battery 1 is reduced in size and weight so that, for example, an operator can easily insert and remove the battery into and from the electric vehicle. Examples of an operator include a working robot.

As shown in FIG. 1, in the replaceable battery 1, the outside shape of a rectangular parallelepiped is defined by a case 100 for accommodating a cell stack or the like. The case 100 includes a case main body 101 having a rectangular tube shape, a front case 102 serving as a lid part for closing an opening part (namely, one opening end) at the front end of the case main body 101, and a rear case 103 serving as a lid part for closing an opening part (namely, the other opening end) at the rear end of the case main body 101. The rear case 103 provided at the rear end of the replaceable battery 1 includes a connector 104 protruding outward and formed to be connectable to a connector on the vehicle side. For example, when an operator accommodates the replaceable battery 1 in in housing space of the vehicle while sliding the replaceable battery 1 in the longitudinal direction (X-axis direction), the connector 104 of the replaceable battery 1 and the connector on the vehicle side are connected.

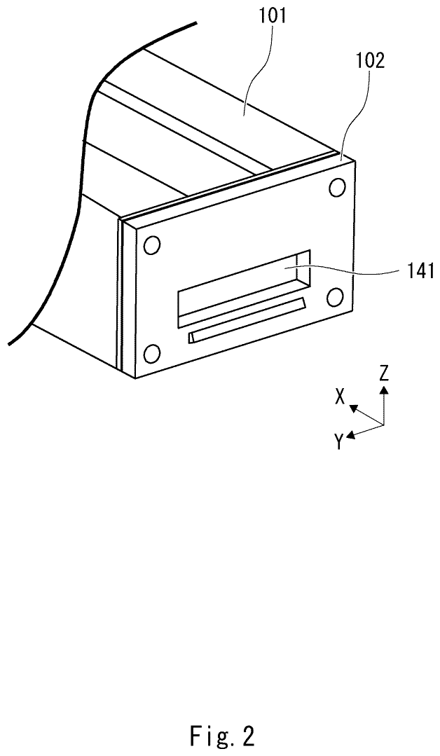

FIG. 2 is an enlarged schematic perspective view of the periphery of the front case 102 provided at the front end of the replaceable battery 1. As shown in FIG. 2, the front case 102 is provided with a pull-handle 141 for sliding the replaceable battery 1. An operator can slide the replaceable battery 1 by holding the pull-handle 141 and pushing or pulling the replaceable battery 1.

In addition, the replaceable battery 1 can be placed on, for example, a carriage and transported. When unloading the replaceable battery 1 from the carriage and housing it in the housing space, the height of the carriage is made to match with that of the housing space, and the replaceable battery 1 is housed in the housing space by pushing the pull-handle 141. On the other hand, when taking the replaceable battery 1 out of the housing space and loading it on the carriage, the height of the carriage is made to match that of the housing space, and the replaceable battery 1 is taken out of the housing space by pulling the pull-handle 141.

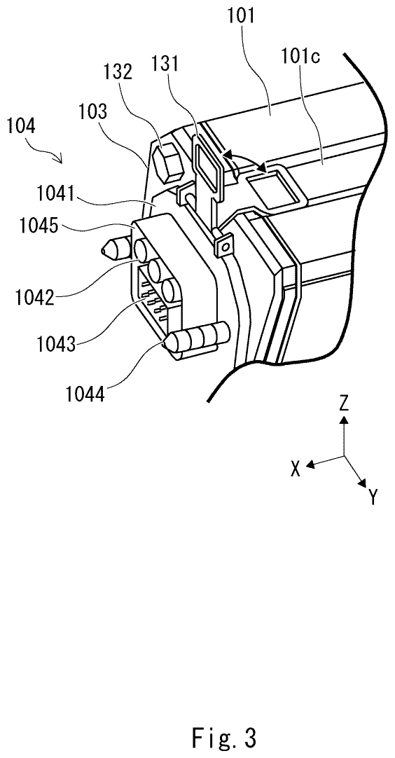

FIG. 3 is an enlarged schematic perspective view of the periphery of the rear case 103 provided at the rear end of the replaceable battery 1. As shown in FIG. 3, in addition to the connector 104, the rear case 103 is provided with a grip-handle 131 and a relief valve 132.

The connector 104 includes a base part 1041, a high-voltage terminal 1042, a low-voltage terminal 1043, an alignment pin 1044, and a metal cover 1045. The base part 1041 is disposed on the main surface of the rear case 103. The high-voltage terminal 1042, the low-voltage terminal 1043, and the alignment pin 1044 are each formed so at to project outwardly from the main surface of the base part 1041. The cover 1045 is formed to surround the side surfaces of the high-voltage terminal 1042 and the low-voltage terminal 1043. The high-voltage terminal 1042 is a terminal for transmitting electricity output from the cell stack housed in the case 100 of the replaceable battery 1 to a vehicle in which the replaceable battery 1 is mounted. The low-voltage terminal 1043 is a terminal for transmitting a control signal directed from the vehicle to the replaceable battery 1, and for transmitting a signal representing a monitoring result (a voltage measurement result, etc.) of the cell stack from the replaceable battery 1 to the vehicle.

The relief valve 132 discharges gas generated in the cell stack housed in the case 100 of the replaceable battery 1. Here, even when gas is discharged from the relief valve 132, the high-voltage terminal 1042 and the low-voltage terminal 1043 are protected by the metal cover 1045.

The grip-handle 131 is rotatably provided around an axis extending along the upper edge of the rear case 103, and is mounted on the upper surface of the case main body 101 when not in use. Therefore, the rear end of the replaceable battery 1 can be suspended by the grip-handle 131 without obstructing the connection of the connector 104.

More specifically, when an operator carries the replaceable battery 1, the replaceable battery 1 is lifted by the grip-handle 131 which is rotatable by one hand, and the replaceable battery 1 is supported by the pull-handle 141 by the other hand. Therefore, the operator can carry the replaceable battery 1 while stabilizing the center of gravity (i.e., maintaining balance).

Here, a rib groove 101c is formed on the upper surface of the case main body 101 along the longitudinal direction (X-axis direction) of the case main body 101. Therefore, the grip-handle 131 is accommodated in the rib groove 101c when not in use. This makes it easier for an operator to house the replaceable battery 1 in a housing space of the vehicle. Further, by forming the rib groove 101c, the strength of the upper surface of the case main body 101 is also improved.

The thickness of the case main body 101 is preferably made small, and the thickness of the rear case 103 is preferably larger than the thickness of the case main body 101. The case 100 is reduced in weight by reducing the thickness of the case main body 101, and the deformation of the case 100 is suppressed by providing the grip-handle 131 on the rear case 103 which is thicker. For example, a die-cast member is used as the rear case 103. With this configuration, the rigidity of the rear case 103 on which the grip-handle 131 is provided is improved, and the workability when the grip-handle 131 is used is also improved. Moreover, by reducing the thickness of the case main body 101, even when gas is generated in a cell stack 110, the case main body 101 is elastically deformed and inflates outward, so that a rapid increase in the internal pressure of the case is suppressed.

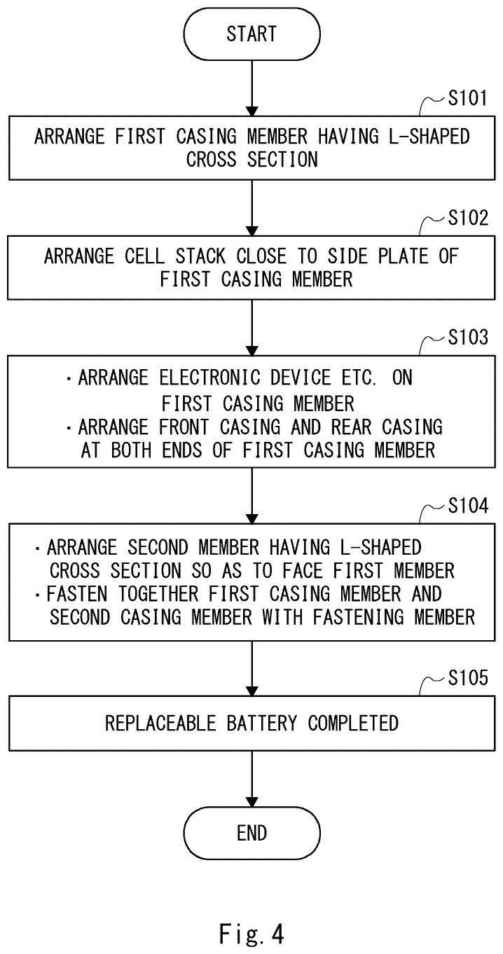

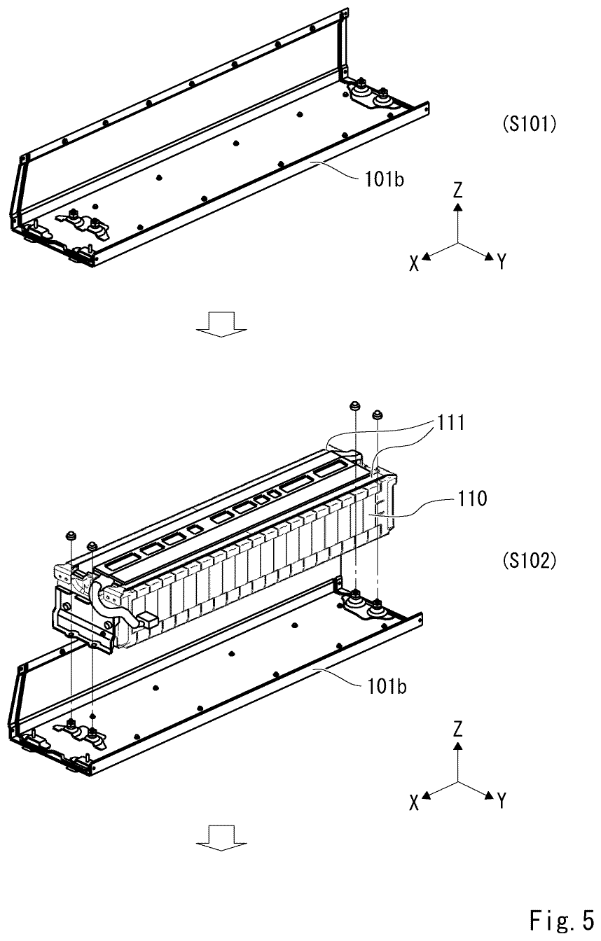

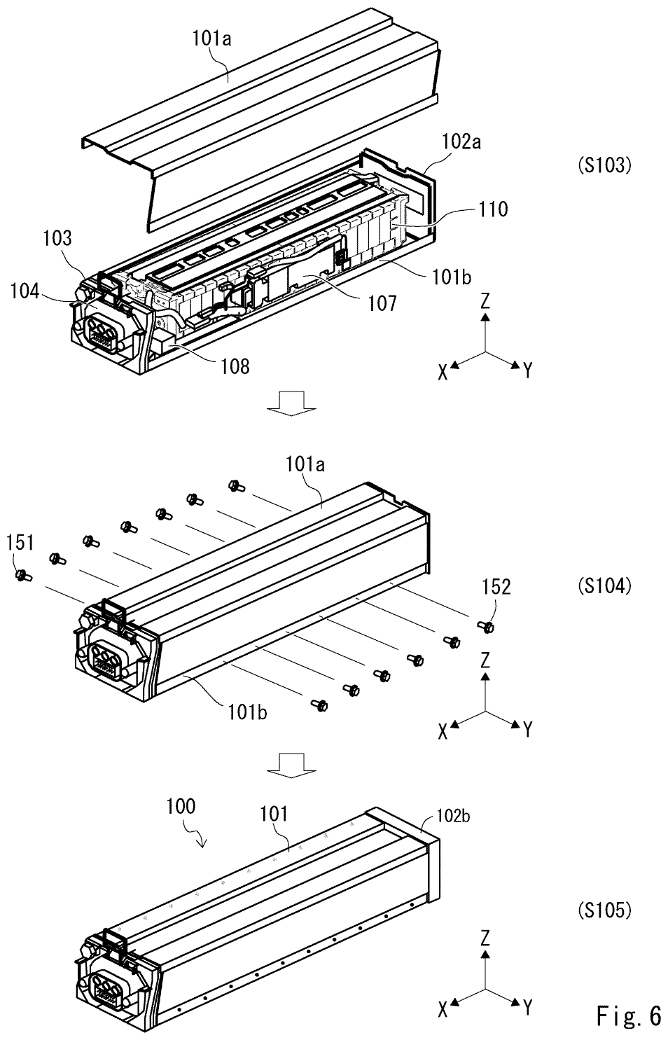

Next, the flow of assembly of the replaceable battery 1 will be described with reference to FIGS. 4 to 6, while the contents contained in the case 100 of the replaceable battery 1 are described. FIG. 4 is a flowchart showing the flow of assembly of the replaceable battery 1. FIGS. 5 and 6 are schematic perspective views for explaining the flow of assembly of the replaceable battery 1. The display contents of Steps S101 to S105 in FIGS. 5 and 6 correspond to the processing results of Steps S101 to S105 in FIG. 4.

First, a lower case 101b forming the bottom plate and one side plate of the case main body 101 are arranged (Step S101). The lower case 101b is formed so that its YZ section is L-shaped and extends along the X-axis direction.

Then, the cell stack 110 having a rectangular parallelepiped shape is arranged on the upper side of the bottom plate formed by the lower case 101b so as to be close to one side plate formed by the lower case 101b (Step S102). The cell stack 110 is configured by laminating a plurality of battery cells and is bundled into a rectangular parallelepiped shape by a binding member 111 such as a binding band.

Then, electronic devices such as a junction box 108 including a relay and a battery monitoring apparatus 107 are further arranged on the upper side of the bottom plate formed by the lower case 101b (Step S103). The battery monitoring apparatus 107 includes a voltage measuring device for measuring the voltage of the cell stack 110 and the voltage of each battery cell configuring the cell stack. The battery monitoring apparatus 107 is arranged in a spatial region between the cell stack 110 and the other side plate of the case main body 101 to be described later in the upper region of the bottom plate formed by the lower case 101b. This spatial region is formed by arranging the cell stack 110 close to one side plate of the case main body 101. The junction box 108 is arranged in a spatial region between the rear end of the cell stack 110 and the rear case 103 to be described later.

An inner-side case 102a of the front case 102 is arranged at the front end of the lower case 101b (the case main body 101) (Step S103). The rear case 103 including the connector 104 is arranged at the rear end of the lower case 101b (the case main body 101) (Step S103).

Thereafter, an upper case 101a forming a top plate and the other side plate of the case main body 101 are arranged so as to face the lower case 101b (Step S104). The upper case 101a is formed so that its YZ section is L-shaped and extends along the X-axis direction. The case main body 101 having a rectangular tube shape is formed of the upper case 101a and the lower case 101b. A spatial region 160 is provided above the cell stack 110 in the internal region of the case main body 101. The spatial region 160 is also used as a smoke exhaust region for releasing gas generated in the cell stack 110. For example, gas generated in the cell stack 110 is discharged from the spatial region 160 to the outside of the case 100 via the relief valve 132.

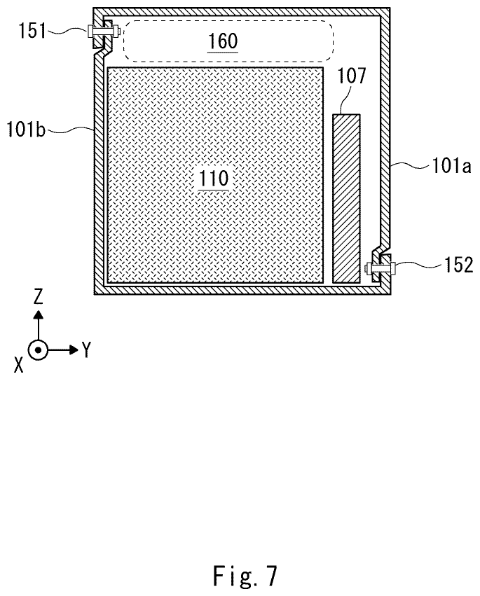

The upper case 101a and the lower case 101b are fastened together with fastening members 151,152 (Step $104). FIG. 7 is a schematic cross-sectional view of the replaceable battery 1. As shown in FIG. 7, an end of one side plate formed by the lower case 101b that protrudes from the spatial region 160 and an end of the top plate formed by the upper case 101a are fastened by the fastening member 151. An end of the other side plate formed by the upper case 101a and an end of the bottom plate formed by the lower case 101b are fastened together with the fastening member 152. As a result, the cell stack 110 can be arranged close to one side plate formed by the lower case 101b without causing any interference of the fastening member 151 with the cell stack 110. Thus, for example, a spatial region sufficient for arranging the battery monitoring apparatus 107 is secured between the cell stack 110 and the other side plate formed by the upper case 101a.

Thereafter, an outer-side case 102b of the front case 102 is arranged at the front end of the case main body 101. Thus, the replaceable battery 1 is completed (Step S105). The case 102b has a cap shape and is attached so as to wrap the opening part (an opening end) at the front end of the case main body 101 from the side surface. Thus, before the gas is discharged from the relief valve 132, it is possible to suppress the gas from leaking out from the side of the front case 102 where an operator is working.

Thus, in the replaceable battery 1 according to the present disclosure, among the regions of a plurality of members forming the case, the regions overhanging the spatial region provided at the upper part of the case are fastened together with a fastening member. Thus, in the replaceable battery 1 according to the present disclosure, the cell stack can be arranged close to the side plate on one side of the case without causing any interference of the fastening member with the cell stack. Thus, for example, a sufficient spatial region for arranging an electronic device such as a battery monitoring apparatus can be secured between a cell stack and a side plate on the other side of the case. That is, the replaceable battery 1 according to the present disclosure can improve space efficiency in the case while preventing interference of a fastening member with the cell stack. In other words, the replaceable battery 1 according to the present disclosure can effectively utilize the spatial region.

In the replaceable battery 1 according to the present disclosure, the heavy cell stack is arranged to one side in the case. Therefore, an operator tends to lose the balance when carrying the replaceable battery 1 due to the misalignment of the center of gravity of the replaceable battery 1. On the other hand, in the replaceable battery 1 according to the present disclosure, as described above, one end of the replaceable battery 1 can be lifted by the rotatable the grip-handle 131 so as to be suspended. More specifically, when carrying the replaceable battery 1, an operator lifts the replaceable battery 1 by holding the rotatable the grip-handle 131 with one hand and supporting the replaceable battery 1 by holding the pull-handle 141 with the other hand. Therefore, an operator can carry the replaceable battery 1 while stabilizing the center of gravity (maintaining the balance).

Further, in the replaceable battery according to the present disclosure, since the case main body is composed of a pair of members having an L-shaped cross section, it becomes easy to house objects-to-be accommodated such as a cell stack in the case during assembly. That is, with a replaceable battery according to the present disclosure, it is possible to improve workability during assembly.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A replaceable battery removably mounted on a vehicle, the battery comprising at least:
a rectangular parallelepiped cell stack having a plurality of battery cells stacked thereon; and
a case for accommodating the cell stack,
wherein the case comprises:
a first member having an L-shaped cross section that includes a bottom plate for supporting the cell stack and extends along a side surface of the cell stack;
a second member having an L-shaped cross section that is arranged to face the first member to thereby form a rectangular tube shaped main body part with the first member, and extends along a side surface of the cell stack;
a first lid part for closing one opening end of the main body part; and
a second lid part having a connector protruding outward so as to be connectable to the vehicle and closing the other opening end of the rectangular tube shaped main body part,
and wherein
the cell stack is arranged closer to a side plate of the first member than to a side plate of the second member,
the case has a spatial region above the cell stack, and
a region of the side plate of the first member overhanging the spatial region and a top plate of the second member are fastened together with a fastening member.

2. The replaceable battery according to claim 1, wherein the spatial region is a smoke exhaust region for releasing gas generated in the cell stack.

3. The replaceable battery according to claim 1, further comprising an electronic device including a voltage measuring device for measuring voltages of the plurality of the battery cells,
wherein the electronic device is provided between the cell stack and the side plate of the second member.

4. The replaceable battery according to claim 1, wherein
the replaceable battery is attached to and detached from the vehicle by sliding the replaceable battery longitudinally,
the first lid part has a pull-handle, and
the second lid part has a grip-handle.

5. The replaceable battery according to claim 4, wherein
a rib groove extends in a longitudinal direction of the main body part on an upper surface of the main body part, and
the grip-handle is accommodated in the rib groove when not in use.
